(19) United States
(12) Patent Application Publication
(10) Pub. No.: US 2006/0159920 A1
(43) Pub. Date: Jul. 20, 2006

(54) Microstructured effect pigments

(76) Inventors: Peter Reynders, Griesheim (DE); Reinhold Rueger, Roedermark (DE); Michael Jungnitz, Langen (DE); Michael Ukelis, Riedstadt (DE); Gerhard Pfaff, Muenster (DE); Volker Hilarius, Gross-Umstadt (DE); Gerald Fuchs-Pohl, Weiterstadt (DE)

Correspondence Address: MILLEN, WHITE, ZELANO & BRANIGAN, PC, 2200 CLARENDON BLVD, SUITE 1400, ARLINGTON, VA, 22201, US

(21) Appl. No.: 10/533,641

(22) PCT Filed: Oct. 17, 2003
(86) PCT No.: PCT/EP03/11508

§ 371 Date: May 3, 2005

(30) Foreign Application Priority Data
Nov. 4, 2002 (DE) 102 51 534.4

(51) Int. Cl. B32B 1/00; B32B 5/16; B05D 7/00; B05D 3/02; C23C 16/00

(52) U.S. Cl. 428/402; 428/403; 427/212; 427/248.1; 427/226

(57) ABSTRACT

The invention relates to flake-form effect pigments, characterised in that they consist of transparent or semitransparent materials and have a groove or grid structure, to processes for the production thereof, and to the use thereof.

The invention relates to flake-form effect pigments, characterised in that the flakes are transparent or semitransparent and have a regular groove or grid structure, to processes for the production thereof, and to the use thereof.

The achievement of angle-dependent optical effects in the coating of two-dimensional materials with thin layers has been known for some time. The prerequisite for this is a difference in the refractive indices of the thin layers compared with those of the surrounding media. In physical terms, partial reflection occurs on incidence of light at the phase boundaries. If the thicknesses of the layers are in the order of magnitude of the wavelength of light, the light components reflected at the phase boundaries interfere, and extinction or reinforcement of certain wavelength regions occurs in white light. This results in coloured light, whose colour depends on the viewing angle. Suitable two-dimensional materials are films, foils, but also flakes, which may be coated with the materials of different refractive index. An overview of the principles of angle-dependent optical effects is given in G. Pfaff, P. Reynders, Chem. Rev., 1999, 99, 1963-1981.

Angle-dependent optical effects can alternatively also be produced via grid structures, where the grid constant is preferably in the order of magnitude of from half the wavelength of light to three times the wavelength of light. The said grids can be the three-dimensional regular arrangement of spheres or cavities of equal size, a structural feature, as occurs, for example, in the opals known from nature. Such bodies exhibit discrete to intense interference colours, provided that they are transparent to light. U.S. Pat. No. 6,261,469 describes the production of periodic structures of this type, with the structural feature being regarded as similar to natural opals. The above-mentioned products are not suitable for use in surface coatings and printing inks since multilayered grids are necessary for the occurrence of the interference colour and as a consequence particles of this type are too large for these applications.

Analogous effects can also be achieved by films having a structured surface, with the grid structures again being regular and in the order of magnitude of from half to three times the wavelength of light. The films usually comprise a highly reflective metal layer, which is essential for the occurrence of strong interference colours. The structures are usually embossed, with the film either being embossed itself or a thermoplastic coating being embossed, if necessary after warming. The area of application of these films is principally in decorative applications, such as, for example, for gift foils.

U.S. Pat. No. 5,464,690 describes composite materials comprising a film and a coating, where a diffraction pattern or holographic image is embossed on the coating. The coating and thus the optical element can be transferred to another substrate by heat sealing.

However, direct use of the films or the transfer of optical layers by heat sealing is only of limited applicability. The methods are not suitable for relatively large or highly curved surfaces, nor for the production of paints and surface coatings.

JP63172779 claims a surface coating with interference colours which comprises interference pigments obtained by comminution of films having a structured surface. The pigments consist of aluminium or of aluminium-coated polymer film.

WO 9323481 describes structured metal pigments obtained by vapour deposition coating of an embossed film with metal, detachment and comminution of the vapour-deposited metal film. Layer packages comprising metal layers and dielectric layers can also be applied by vapour deposition. Thus, multilayered pigments having a grid structure can be obtained. The pigments exhibit strongly angle-dependent colours and can be employed, for example, in surface coatings and in security printing.

The structured pigments described above consist either of metal flakes or comprise at least one metal layer and are thus opaque to light. The lack of transparency of these pigments greatly restricts their potential applications in paints and surface coatings since there are virtually no opportunities for colour mixing, as is necessary for the surface coatings usually used. In order to achieve special colour effects, such pigments have to be applied in multicoat finishes, which means considerably increased work during coating and also during repair of any damage. These pigments are also unsuitable for the production of transparent articles, such as films, owing to their opacity to light.

There is therefore an urgent demand for pigments having an angle-dependent colour which can be formulated to a broad extent with other pigments and colorants and which exhibit the depth effect known of conventional pearlescent pigments. In addition, the pigments should be thermally stable and chemically inert.

Surprisingly, it has been found that the microstructured effect pigments according to the invention achieve the complex requirement profile mentioned above. The invention therefore relates to flake-form effect pigments, characterised in that the flakes are transparent or semitransparent and have a regular groove or grid structure.

The effect pigments according to the invention exhibit the depth lustre which is typical of pearlescent pigments and at the same time exhibit a discrete colour play when viewed at a flat angle. In addition, the pigments are thermally stable and chemically inert. Owing to the transparency of the effect pigments according to the invention, they are particularly suitable for use in blends with other pigments and facilitate a wide variety of colour compositions with a series of colour shades at changing viewing angles. In contrast to the situation in the case of structured pigments having metal layers from the prior art, which virtually only act in pale hues, the effect pigments according to the invention are also suitable in dark hues. In addition, the combination of colour effects as a consequence of the structure with interference phenomena in the case of multilayered effect pigments enables novel colour effects to be achieved. Furthermore, the pigments according to the invention are suitable for use in transparent materials, such as, for example, films or plastic sheets.

The particular colour effects are caused by the groove or grid structure of the effect pigments according to the invention. The groove or grid structure is located on the surface or in the body of the transparent or semitransparent flakes and can consist of regularly arranged, parallel or crossed lines, hemispheres, spheres, pyramids, cubes or correspondingly shaped holes. The geometrical shape of the groove or grid elements is of secondary importance for the colour effect; the important factor is the uniformity of the size of the groove or grid elements and their separations. In order to achieve particularly intense colour effects, the separations of the groove or grid elements are in the range 250-2000 nm and are thus in the order of magnitude of the wavelength of light.

The effect pigments according to the invention consist of transparent or semitransparent flakes, where the transparency of the pigments according to the invention is >20%, preferably >50%, based on the individual particle and on white light from a quartz lamp. Methods for the determination of the transparency of small flakes are known, and instruments for this purpose are commercially available. For example, a microspectrometer from the SEE 1000 series from SEE Inc, Middleborough, Mass.; USA, is suitable. Suitable materials for the transparent or semitransparent flakes are, for example, magnesium fluoride, metal oxides, metal suboxides, nitrides, oxynitrides or phosphates. The pigments according to the invention preferably consist of one or more layers of the transparent or semitransparent materials.

The transparent or semitransparent materials are preferably metal oxides, such as, for example, silicon oxide, aluminium oxide, iron oxide, zirconium oxide, tantalum oxide or titanium oxide. The effect pigments according to the invention preferably comprise at least one transparent or semitransparent material having a refractive index of >1.7. In particular, the oxides of the elements aluminium, titanium, iron, zirconium or mixtures of these materials are employed for this purpose.

In the simplest embodiment, the effect pigments according to the invention consist only of one layer of a transparent or semitransparent material and have the groove or grid structure on one of the two surfaces. These are preferably layers of metal oxides having a refractive index of >1.7, such as, for example, aluminium oxide, titanium oxide, iron oxide, zirconium oxide or mixtures of these oxides.

The thickness of the pigment flakes can vary in broad ranges and is not crucial for the colour effects occurring. The thickness is preferably 0.3 to 2 μm. The diameter of the pigments according to the invention can be varied in broad ranges, depending on the application. Preferred sizes are in the range from 5 to 500 μm and in particular between 10 and 100 μm.

Alternative effect pigments which are likewise in accordance with the invention comprise a transparent or semitransparent support material which has a groove or grid structure on one of the surfaces and is provided with further layers of a transparent or semitransparent material. Suitable support materials are all transparent or semitransparent materials known to the person skilled in the art, such as, for example, magnesium fluoride, metal oxides, nitrides, oxynitrides, phosphates, but in particular metal oxides, such as, for example, silicon dioxide, titanium dioxide, titanium suboxides, zirconium dioxide, iron(III) oxide, iron titanates or chromium oxide.

The coating can consist of all transparent or semitransparent materials known to the person skilled in the art, such as, for example, metals or metal oxides. Suitable metals are, for example, chromium, aluminium, nickel, silver, gold, titanium or copper. In order to guarantee the semitransparency of the metal layers, the thickness of the metal layers, depending on the metal, is 3 to 20 nm, preferably 5 to 10 nm. The coating preferably consists of metal oxides and in particular of metal oxides having a refractive index of >1.7, such as, for example, aluminium oxide, titanium oxide, iron oxide, zirconium oxide or mixtures of these oxides. The coating of the support material with at least one further layer enables the colour effects of the pigments according to the invention to be varied through interference phenomena. The thickness of the metal-oxide coating on the support material is 10 to 300 nm, preferably 20 to 150 nm. Through control of the thickness of the coating in a manner familiar to the person skilled in the art, the colour effects achieved by the pigments according to the invention can be influenced further.

In a further embodiment, the pigments according to the invention are formed by the regular arrangement of monodisperse spheres of transparent or semitransparent materials embedded in a matrix. In the simplest embodiment, the monodisperse spheres consist, for example, of polymers or a metal oxide, preferably having a refractive index >1.7, such as, for example, aluminium oxide, titanium oxide or zirconium oxide. Alternatively, the monodisperse spheres may also consist of other transparent or semitransparent materials and be provided with further layers. The sphere bodies are preferably of metal oxides and in particular of silicon oxide. These spheres may be coated with other transparent or semitransparent materials, preferably with a metal oxide having a refractive index >1.7. Particularly suitable for this purpose are titanium oxide, aluminium oxide, iron oxide, zirconium oxide or mixtures of these materials. However, the spheres may also comprise semitransparent or opaque metal layers, provided that the transparency of the flakes comprising such spheres is greater than 20%.

The structure of the monodisperse spheres and processes for the production thereof are described, for example, in EP 0 803 550. The diameter of the spheres can be 100 to 1000 nm, preferably 200 to 700 nm. In order to fix the coated or uncoated spheres, they are embedded in a matrix in the case of the pigments according to the invention. The material for the matrix can be organic binders, but also inorganic materials. Suitable organic binders are all film-forming organic polymers known to the person skilled in the art which can be crosslinked after formation of the film and formation of the regular grid structure. Suitable matrix materials are, for example, epoxy resins, melamine-formaldehyde resins or acrylates. Suitable inorganic matrix materials are, in particular, network-forming materials, such as, for example, metal titanates, metal aluminates, oxides, such as titanium oxide, aluminium oxide, zirconium oxide or silicon oxide. Preference is given to the use of silicon dioxide.

A process for the production of structured metal-based pigments which is mentioned in the prior art is substantially based on the embossing of structures in existing metal foils. This process is not suitable for the production of the effect pigments according to the invention. Another known process is based on the coating of a structured foil by vacuum vapour deposition. This process is very complex, the vapour deposition coating with low-volatility metal oxides requires high energy expenditure and long residence times.

The invention therefore also relates to processes for the production of the effect pigments according to the invention, characterised in that a body provided with a groove or grid structure is coated with a transparent or semitransparent material, and the flake-form effect pigment is obtained either by detachment from the structured body or by separation from a support together with the structured body. In a further embodiment, the effect pigments according to the invention produced by this process may additionally be coated with further layers of a transparent or semitransparent material, for example with metal oxides or metals, such as, for example, chromium, aluminium, nickel, silver, gold, titanium or copper. The coating is preferably carried out with metal oxides and in particular with silicon dioxide, aluminium oxide, titanium oxide, iron oxide, zirconium oxide or mixtures of these oxides. In this way, pigments which exhibit particularly intense colours can be produced.

The bodies provided with a grid structure can be, for example, in the form of a correspondingly structured film, a structured tape or a drum having a structured surface. Other structured materials known to the person skilled in the art can likewise be employed. The grid structure on the bodies can consist of regularly arranged, parallel or crossed grooves, lines, hemispheres, spheres, pyramids, cubes or correspondingly shaped holes. Preference is given to the use of grids comprising regularly arranged grooves or spheres.

Grids comprising regularly arranged spheres can be produced, for example, by application of a suspension of monodisperse spheres and a film-forming matrix to a support having a smooth surface, such as, for example, a film. EP 0 216 278 discloses monodisperse spheres of this type. After application of the film, the particles are further arranged in closest spherical packing by the surface forces and the material transport during the drying operation. The interspaces between the spheres themselves and the interspaces between the spheres and the surface of the support are filled by the matrix material. Suitable matrix materials are the transparent or semitransparent materials mentioned in this application, but also organic binders. The formation of nanostructures of this type by self-organisation of particles and the mechanisms for this are described, for example, by F. Burmeister, J. Boneberg, P. Leiderer, Physikalische Blätter 2000, 56, 49-50. The particles arranged in this way can be fixed in the matrix by crosslinking of the film-forming matrix material. The crosslinking here can take place in all manners known to the person skilled in the art, such as, for example, condensation or addition reactions, polymerisation of suitable monomers and by thermally, photochemically or pH-induced crosslinking. The film obtained can be dried, washed and detached from the support. In this way, bodies structured with spheres are obtained which can be employed in the process for the production of the pigments according to the invention. In addition, this procedure is also suitable for the direct production of the particular embodiment of the pigments according to the invention in which a combination of a regular grid of coated spheres with a transparent or semitransparent material is present. The pigments according to the invention can be obtained by detachment of the film from the spheres embedded in the binder and comminuting the film. The sphere grid is accordingly located in the body of the pigments according to the invention. Preference is given to the use of spheres made from materials of high refractive index (>1.7) or spheres coated with high-refractive-index materials.

The coating of the structured bodies for the production of the pigments according to the invention can be carried out wet-chemically, by the sol-gel process or via PVD or CVD processes. The structured body here can be applied to a support, such as, for example, an embossed release layer on a film or a drum.

In the case of coating by the sol-gel process, metal alkoxides are preferably applied to the structured bodies in the form of a solution, the metal alkoxides are decomposed hydrolytically using water, the resultant film is dried and either detached from the structured body or detached from a support in combination with the structured body. Further embodiments can be derived by the person skilled in the art in an obvious manner.

Alternatively, the coating can also be carried out wet-chemically, for example by application of aqueous sols and solutions to the structured bodies, precipitation of a layer, drying and detachment of the coating from the body or from a support together with the body. A preferred example is the deposition of silicon dioxide from water-glass. In addition, all processes known to the person skilled in the art for the precipitation and formation of the layer-forming materials are suitable.

The coating of a structured body for the production of the effect pigments according to the invention can also be carried out via PVD or CVD processes. These processes are known from the literature, for example from U.S. Pat. No. 3,123,489.

In the coating, the body structure is in the simplest case transferred to the coating material. The structured body acts in the coating as negative for the surface of the pigment particles that was in contact with the body. The opposite surface which was not in contact with the body generally exhibits only a weak image of the relief and may be completely flat in the case of thicker particles. The pigments according to the invention formed in this way can be detached from the structured support material and comminuted. Alternatively, pigments according to the invention can be obtained if the transparent or semitransparent material applied is separated off in combination with the structured body. This procedure is particularly suitable for the production of the pigments according to the invention in which a regular grid of mono- or multicoated spheres is present.

In a further embodiment, the resultant pigments according to the invention can be coated further, for example with metal oxides or metals, optionally mixed with colorants. Suitable metals here are, for example, chromium, aluminium, nickel, silver, gold, titanium or copper. Suitable for the deposition of the metals by CVD or PVD processes are all precursors and process variants known to the person skilled in the art. In addition, the transparent or semitransparent materials of the pigments according to the invention may likewise, in their respective embodiment, comprise colorants for further colouring of the pigments.

Further processes for the production of the effect pigments according to the invention can be used in a manner familiar to the person skilled in the art.

Owing to their advantageous properties, the effect pigments according to the invention are suitable for a broad range of applications. The invention therefore also relates to the use of the effect pigments according to the invention in cosmetics, surface coatings, paints, plastics, films, in security printing, as security feature in documents and identity cards, for laser marking, for colouring seed, for colouring foods or in medicament coatings.

In the case of cosmetics, the pigments according to the invention are particularly suitable for products in decorative cosmetics, such as, for example, nail varnishes, colouring powders, lipsticks or eyeshadows. On use of the pigments in paints and surface coatings, all areas of application known to the person skilled in the art are possible, such as, for example, powder coatings, automobile paints, printing inks for gravure, offset, screen or flexographic printing and for surface coatings in outdoor applications. In addition, the pigments according to the invention can be used for pigmenting films and plastics, for example for agricultural sheeting, infrared-reflective films and panes, gift foils, plastic containers and mouldings for all applications known to the person skilled in the art. Owing to the particular angle-dependent colour effects, the pigments according to the invention are also suitable for use in security printing and in security-relevant features for, for example, forgery-proof cards and identity papers, such as, for example, entry tickets, personal identity cards, banknotes, cheques and cheque cards, and for other forgery-proof documents. In the area of agriculture, the pigments can be used for colouring seed and other starting materials, in addition in the foods sector for pigmenting foods. The pigments according to the invention can likewise be employed for pigmenting coatings in medicaments, such as, for example, tablets or dragées.

Owing to the transparency, the effect pigments according to the invention are suitable for the pigmentation of transparent films which retain their transparency and in particular for use in blends are mixed with all known organic and/or inorganic colorants, such as, for example, organic dyes, organic pigments, inorganic single- or multilayered pigments, inorganic dyes or pigments. It is thus possible to achieve in a simple manner novel colour effects which can only be achieved with difficulty using the conventional structured metal-based pigments.

A particular potential application of the effect pigments according to the invention consists in their use as tracers in mixtures with further organic and/or inorganic colorants. Tracers are frequently employed in modern products as identification agents. With their aid, the authenticity of a product can be established or the origin of a product reconstructed. Common tracers are based on fluorescent, radioactive or luminescent substances which are added to the product to be protected in the form of a powder, suspension or liquid. These substances are frequently toxicologically and environmentally unacceptable or require special apparatuses and instruments for their detectability.

The effect pigments according to the invention can be added to the colorants to be marked or products produced therefrom, such as, for example, surface coatings, powders, inks or suspensions, using all methods known to the person skilled in the art. The proportion of the tracer in the product to be marked is usually ≦5% by weight, based on the marked product, and preferably <2% by weight and very particularly preferably 0.1-1% by weight.

Depending on the size of the effect pigments according to the invention, the tracer in the mixtures can be detected very simply by means of a microscope or by means of the scanning electron microscope. Chemically and toxicologically, these tracers behave like other effect pigments and are thus chemically inert and toxicologically acceptable. The effect pigments according to the invention can be admixed in very small dosage, so that the colouristic properties in the application are thus not significantly influenced. Since the effect pigments according to the invention specifically adapted to the customer wishes for this application are not commercially available, adequate copy protection of the mixture to be marked is ensured.

Owing to the stability and chemically inert character, the effect pigments according to the invention can be employed simply and without problems and converted into formulations. This invention likewise relates to formulations comprising the effect pigments according to the invention.

The following examples are intended to explain the invention in greater detail, but without limiting it.

### EXAMPLES

### Example 1

A polyethylene terephthalate film with a thickness of 100 μm whose surface is embossed with a regular groove structure having a groove separation of 1 μm is coated by the dip-casting method with a sodium water-glass solution (23% by weight of sodium orthosilicate) comprising 0.1% by weight of a commercially available wetting agent (for example Triton® X-100) as wetting aid and flow-control agent. The sodium water-glass film is dried using air at 50° C. The dry film with a thickness of about 600 nm is detached from the substrate in the form of coarse flakes and subsequently washed at pH 5, during which the pH of the bath is kept constant using dilute hydrochloric acid. After the washing, the SiO₂ flakes are dried, then calcined at 700° C. and subsequently crushed to give pigment flakes having a diameter of 10-80 μm. The flakes obtained exhibit an exact cast of the groove structure embossed on the film.

A sample of the powder obtained in this way is dry-coated with the finger onto a cardboard sheet onto which black and white fields are pressed. On consideration in an inclined view, the pigment powder coating shimmers in colours which are highly angle-dependent and run through virtually the entire spectrum of the rainbow on tilting of the sheet.

### Example 2

10 g of the flakes from Example 1 are suspended in 250 ml of water. An SnCl₄ solution (preparation: 1.1 g of SnCl₄.5H₂O dissolved in 2 ml of conc. hydrochloric acid and 17 ml of water) is added dropwise at a metering rate of 0.2 ml/min with vigorous stirring at 75° C. and pH 1.8. The temperature is subsequently raised to 90° C., the pH is lowered to 1.5, and 20 ml of a TiCl₄ solution (content: 380 g of TiCl₄ per litre) are added dropwise. The pH is kept constant by addition of dilute sodium hydroxide solution. When the addition is complete, the product obtained is filtered off, washed and dried, giving a silvery white powder that exhibits intense angle-dependent interference colours on spreading on a support.

### Example 3

A PET film with a thickness of 0.1 mm whose surface is embossed with a regular groove structure having a frequency of 1000 lines per millimetre and a depth of 150 nm is coated with a 5% aqueous zirconium dioxide sol (particle size 2 nm) using a hand coater. The casting solution was prepared by dilution of a commercially available zirconium dioxide sol from Merck KGaA and addition of 0.1% of a commercially available wetting agent (for example Triton® X114). The wet-layer thickness is about 25 μm. The aqueous film is dried in air, the dry layer is detached to give flakes. The zirconium dioxide flakes obtained exhibit a precise copy of the surface structure of the film and very intense interference colours. The zirconium dioxide flakes are then calcined at 700° C. and comminuted further by means of ultrasound to give pigment flakes. A sample of the pigments obtained in this way is suspended in a nitrocellulose lacquer and applied to a dark-blue plastic card. The coated plastic card exhibits angle-dependent intense colours over the blue base shade.

### Example 4

The film described in Example 3 is coated by the dip-casting method with a 0.5 molar solution of chlorotriisopropyl orthotitanate in hexane/ethanol (1:1 mixture) and dried in air. Firstly a clear gel film forms, which is slowly converted into titanium oxide in moist air. At the end, the film is treated with hot steam, detached from the substrate, rubbed down to give flakes and briefly heated to 700° C. After cooling, a white pigment powder is obtained. Spread on a black board, the pigment powder exhibits bright angle-dependent colours and a strong glitter effect.

### Example 5

Microstructured effect pigments according to Example 1 are admixed with a proportion of 0.1% by weight, based on the total amount, with the pigment powder to be protected (Colorstream® Viola Fantasy, silicon dioxide coated with titanium dioxide, tin oxide and zirconium oxide, Merck KGaA). In order to check the protected mixture, the powder is placed on a specimen slide and investigated by means of a microscope. Under the microscope, the characteristic structuring of the tracer are evident. The addition of the tracer does not result in a change of the applicational properties of the pigment powder to be protected.

1. Flake-form effect pigments, characterised in that the flakes are transparent or semitransparent and have a regular groove or grid structure.

2. Flake-form effect pigments according to claim 1, characterised in that they consist of one or more layers of transparent or semitransparent materials.

3. Flake-form effect pigments according to claim 1, characterised in that the groove or grid structure is located on the surface or in the body of the transparent or semitransparent flakes.

4. Flake-form effect pigments according to claim 1, characterised in that the separations in the groove or grid structure are in the range from 250 to 2000 nm.

5. Flake-form effect pigments according to claim 1, characterised in that the transparency of the flakes is >20%.

6. Flake-form effect pigments according to claim 1, characterised in that the groove or grid structure consists of regularly arranged lines, hemispheres, spheres, pyramids, cubes or correspondingly shaped holes.

7. Flake-form effect pigments according to claim 6, characterised in that the spheres are mono- or multicoated spheres.

8. Flake-form effect pigments according to claim 1, characterised in that the transparent or semitransparent materials are magnesium fluoride, metals, metal oxides, metal suboxides, metal nitrides, metal oxynitrides or phosphates.

9. Flake-form effect pigments according to claim 1, characterised in that at least one of the transparent or semitransparent materials has a refractive index >1.7.

10. Flake-form effect pigments according to claim 9, characterised in that the material layer having a refractive index >1.7 consists of aluminium oxide, titanium oxide, iron oxide, zirconium oxide or of mixtures of these materials.

11. Process for the production of flake-form effect pigments according to claim 1, characterised in that a body provided with a groove or grid structure is coated with a transparent or semitransparent material, and the flake-form effect pigment is obtained either by detachment from the structured body or by separation from a support together with the structured body.

12. Process according to claim 11, characterised in that the body provided with a grid structure has regularly arranged grooves or spheres.

13. Process according to claim 12, characterised in that the spheres are mono- or multicoated spheres.

14. Process according to claim 11, characterised in that the flake-form effect pigments are coated with further layers of a transparent or semitransparent material.

15. Process according to claim 14, characterised in that the semitransparent material is a metal.

16. Process according to claim 11, characterised in that the coating is carried out wet-chemically, by the sol-gel process or via PVD or CVD processes.

17. Use of flake-form effect pigments according to claim 1 in cosmetics, paints, surface coatings, plastics, films, in security printing, as security feature in documents and identity cards, as tracers, for laser marking, in heat protection, for colouring seed, for colouring foods or in medicament coatings.

18. Formulations comprising flake-form effect pigments according to claim 1.
